(19) United States
(12) Patent Application Publication
(10) Pub. No.: US 2017/0261558 A1
(43) Pub. Date: Sep. 14, 2017

(54) Systems And Methods For Testing Ground Fault Circuit Interrupter Breakers

(71) Applicant: Cooper Technologies Company, Houston, TX (US)

(72) Inventor: Benjamin Avery Freer, Syracuse, NY (US)

(21) Appl. No.: 15/448,211

(22) Filed: Mar. 2, 2017

Related U.S. Application Data
(60) Provisional application No. 62/305,684, filed on Mar. 9, 2016.

(51) Int. Cl. G01R 31/327; H01H 9/54

(52) U.S. Cl. CPC G01R 31/3277; H01H 9/54

(57) ABSTRACT

A testing circuit assembly can include a first variable resistive load configurable for a range of electrical resistances, where the first variable resistive load is configured to couple to at least one first ground fault circuit interrupter (GFCI) breaker and a current source. The testing circuit assembly can also include a first local controller coupled to the first variable resistive load, where the first local controller controls the first variable resistive load to simulate a range of fault currents, corresponding to the range of electrical resistances, flowing to the at least one first GFCI breaker to determine at least one actual trip point of the at least one first GFCI breaker. Each electrical resistance in the range of electrical resistances can correspond to a fault current in the range of fault currents.

### CROSS-REFERENCE TO RELATED APPLICATIONS

This application claims priority under 35 U.S.C. §119 to U.S. Provisional Patent Application Ser. No. 62/305,684, titled “Methods and Systems For Testing Ground Fault Circuit Interrupter Breakers” and filed on Mar. 9, 2016, the entire contents of which are hereby incorporated herein by reference.

### TECHNICAL FIELD

The present disclosure relates generally to ground fault circuit interrupter (GFCI) breakers, and more particularly to systems, methods, and devices for testing GFCI breakers.

### BACKGROUND

Enclosures are used in a number of applications and have a number of different sizes and configurations. Such enclosures have one or more electrical devices and/or mechanical devices disposed therein. An example of such a device is a GFCI breaker. The breaker portion of the device is a switch that controls when power is sent to downstream devices (sometimes called “electrical load” herein). The GFCI portion of the device is a fail-safe feature that automatically opens the breaker when a ground fault is detected. In many cases, a GFCI breaker has a fixed threshold for ground current (also called a trip point or a trip setting), and the trip point for a GFCI breaker can vary, depending on the application for which a GFCI breaker is used.

### SUMMARY

In general, in one aspect, the disclosure relates to a testing circuit assembly. The testing circuit assembly can include a first variable resistive load configurable for a range of electrical resistances, where the first variable resistive load is configured to couple to at least one first ground fault circuit interrupter (GFCI) breaker and a current source. The testing circuit assembly can also include a first local controller coupled to the first variable resistive load, where the first local controller controls the first variable resistive load to simulate a range of fault currents, corresponding to the range of electrical resistances, flowing to the at least one first GFCI breaker to determine at least one actual trip point of the at least one first GFCI breaker. Each electrical resistance in the range of electrical resistances corresponds to a fault current in the range of fault currents.

In another aspect, the disclosure can generally relate to a ground fault circuit interrupter (GFCI) breaker testing system. The system can include at least one GFCI breaker having at least one trip point. The system can also include a testing circuit coupled to the at least one GFCI breaker, wherein the testing circuit simulates a range of fault currents through the at least one GFCI breaker, where the at least one trip point corresponds to at least one fault current within the range of fault currents.

In yet another aspect, the disclosure can generally relate to a controller for a testing circuit. The controller can include a control engine that follows a plurality of instructions to control a variable resistive load through which a current flows to a ground fault circuit interrupter (GFCI) breaker as a range of fault currents. The control engine can also follow the plurality of instructions to determine whether the fault current in the range of fault currents at which the GFCI breaker trips.

These and other aspects, objects, features, and embodiments will be apparent from the following description and the appended claims.

### BRIEF DESCRIPTION OF THE DRAWINGS

The drawings illustrate only example embodiments and are therefore not to be considered limiting in scope, as the example embodiments may admit to other equally effective embodiments. The elements and features shown in the drawings are not necessarily to scale, emphasis instead being placed upon clearly illustrating the principles of the example embodiments. Additionally, certain dimensions or positionings may be exaggerated to help visually convey such principles. In the drawings, reference numerals designate like or corresponding, but not necessarily identical, elements.

FIG. 1 shows a front view of an enclosure in which a number of GFCI breakers are disposed in a manner currently known in the art.

FIG. 2 shows a sensing circuit assembly used in conjunction with multiple GFCI breakers in an enclosure in accordance with certain example embodiments.

FIG. 3 shows a graph of testing a GFCI breaker in accordance with certain example embodiments.

FIGS. 4A and 4B show a system in accordance with certain example embodiments.

FIG. 5 shows a computing device in accordance with certain example embodiments.

### DETAILED DESCRIPTION

In general, example embodiments provide systems, methods, and devices for systems for testing GFCI breakers within an enclosure. Example systems for testing GFCI breakers within an enclosure can be used in any of a number of enclosures, including but not limited to junction boxes, circuit panels, and control panels. Further, the enclosures in which example systems for testing GFCI breakers are used can be located in one or more of any of a number of environments, including but not limited to hazardous (e.g., explosive) environments, indoors, outdoors, cold temperatures, hot temperatures, high humidity, marine environments, and low oxygen environments. As described herein, an enclosure can also be called an electrical enclosure. In some cases, example embodiments can be used to test one or more GFCI breakers that are located outside of an enclosure.

In addition, the size (e.g., the voltage rating, the current rating) of GFCI breakers used with example embodiments can vary. For example, a number of GFCI breakers that are coupled to an example testing system can be rated for 120 VAC and 30 A maximum current. Further, multiple GFCI breakers that are coupled to an example testing system can be located in more than one enclosure rather than in a single enclosure. In such a case, the multiple enclosures can be located proximate to each other. For example, the different GFCI breakers can be located in different compartments of a single motor control center (or similar location where multiple compartments are located adjacent to each other).

While example embodiments are directed for use with GFCI breakers as described herein, example systems described herein can be used with any of a number of devices (e.g., breakers that do not have GFCI capability) that are located in a single enclosure (or multiple adjacent enclosures) and that require periodic testing and/or other interaction by a user. For example, the National Fire Protection Association (NFPA) requires that circuit breakers are tested on a periodic basis (e.g., every 30 days, in accordance with the manufacturer's instructions). Example embodiments described herein can be used in new enclosures. In addition, some example embodiments can be used to retrofit existing systems, currently used in the art, to test GFCI breakers.

The GFCI breakers described herein can be designed for any type of voltage (e.g., alternating current, direct current). In addition, the GFCI breakers described herein can be designed for any level of voltage (e.g., 120V, 480V, 4 kV). A user may be any person that interacts, directly or indirectly, with enclosures and/or GFCI breakers. Examples of a user may include, but are not limited to, an engineer, an electrician, an instrumentation and controls technician, a mechanic, an operator, a consultant, a contractor, and a manufacturer's representative.

GFCI breakers can be used in one or more of a number of applications. For example, GFCI breakers can be used for heat tracing, which raises or maintains the temperature of devices (e.g., pipes, vessels, motor controls) using heating elements. Heat tracing can be critical to ensure proper operation of the downstream electrical load and/or to avoid catastrophic failure of the downstream electrical load and associated processes/equipment. Ground shorting is a significant risk in heat tracing applications, and so the proper operation of GFCI breakers used in heat tracing applications is critical. The threshold value of a fault associated with heat tracing can be some multiple (e.g., two times, ten times) larger than the threshold value associated with a ground fault for personnel safety, which is another common application of a GFCI breaker.

In the foregoing figures showing example embodiments of systems for testing GFCI breakers within an enclosure, one or more of the components shown may be omitted, repeated, and/or substituted. Accordingly, example embodiments of systems for testing GFCI breakers within an enclosure should not be considered limited to the specific arrangements of components shown in any of the figures. For example, features shown in one or more figures or described with respect to one embodiment can be applied to another embodiment associated with a different figure or description.

In certain example embodiments, enclosures in which example systems for testing GFCI breakers within an enclosure are used are subject to meeting certain standards and/or requirements. For example, the NFPA, the National Electric Code (NEC), the National Electrical Manufacturers Association (NEMA), the International Electrotechnical Commission (IEC), and the Institute of Electrical and Electronics Engineers (IEEE) can set standards as to electrical enclosures, wiring, and electrical connections. Use of example embodiments described herein meet (and/or allow a corresponding downstream electrical load and/or electrical enclosure to meet) such standards when required. In some (e.g., PV solar) applications, additional standards particular to that application may be met by the electrical enclosures in which example systems for testing GFCI breakers within an enclosure are used.

As discussed above, example embodiments can be used in hazardous environments or locations. Examples of a hazardous location in which example embodiments can be used can include, but are not limited to, an airplane hangar, a drilling rig (as for oil, gas, or water), a production rig (as for oil or gas), a refinery, a chemical plant, a power plant, a mining operation, and a steel mill. A hazardous environment can include an explosion-proof environment, which would require an enclosure with an example systems for testing GFCI breakers to meet one or more requirements, including but not limited to flame paths.

In addition to hazardous environments, an enclosure that includes an example system for testing GFCI breakers can be located in any other type of environment (e.g., indoors, outdoors, under water, in a climate controlled room). As defined herein, a hazardous location is any location where the enclosure (or other environment in which a GFCI breaker is located) can be exposed to extreme conditions. Extreme conditions can include, but are not limited to, high temperatures, low temperatures, temperature fluctuations, corrosion, humidity, chemicals, vibrations, and dust. More information about hazardous locations and hazardous location enclosures can be found, for example, in Articles 500-506 and Articles 510-517 of the NEC, which is incorporated herein by reference.

Examples of a hazardous location in which example embodiments can be used can include, but are not limited to, an airplane hangar, a drilling rig (as for oil, gas, or water), a production rig (as for oil or gas), a refinery, a chemical plant, a power plant, a mining operation, and a steel mill. A hazardous environment can include an explosion-proof environment, which would require an enclosure with an example system for testing GFCI breakers to meet one or more requirements, including but not limited to flame paths.

An explosion-proof enclosure is a type of hazardous location enclosure. In one or more example embodiments, an explosion-proof enclosure (also known as a flame-proof enclosure) is an enclosure that is configured to contain an explosion that originates inside the enclosure. Further, the explosion-proof enclosure is configured to allow gases from inside the enclosure to escape across joints of the enclosure and cool as the gases exit the explosion-proof enclosure. The joints are also known as flame paths and exist where two surfaces meet and provide a path, from inside the explosion-proof enclosure to outside the explosion-proof enclosure, along which one or more gases may travel. A joint may be a mating of any two or more surfaces. Each surface may be any type of surface, including but not limited to a flat surface, a threaded surface, and a serrated surface.

In one or more example embodiments, an explosion-proof enclosure is subject to meeting certain standards and/or requirements. For example, NEMA sets standards with which an electrical enclosure must comply in order to qualify as an explosion-proof enclosure. Specifically, NEMA Type 7, Type 8, Type 9, and Type 10 enclosures set standards with which an explosion-proof enclosure within certain hazardous locations must comply. For example, a NEMA Type 7 standard applies to electrical enclosures constructed for indoor use in certain hazardous locations. Hazardous locations may be defined by one or more of a number of authorities, including but not limited to the NEC (e.g., Class 1, Division I) and UL (e.g., UL 1203). For example, a Class 1 hazardous area under the National Electric Code is an area in which flammable gases or vapors may be present in the air in sufficient quantities to be explosive.

As a specific example, NEMA standards for an explosion-proof enclosure of a certain size or range of sizes (e.g., greater than 100 in³) may require that in a Group B, Division 1 area, any flame path of an explosion-proof enclosure must be at least 1 inch long (continuous and without interruption), and the gap between the surfaces cannot exceed 0.0015 inches. Standards created and maintained by NEMA may be found at www.nema.org/stds and are hereby incorporated by reference.

If a component of a figure is described but not expressly shown or labeled in that figure, the label used for a corresponding component in another figure can be inferred to that component. Conversely, if a component in a figure is labeled but not described, the description for such component can be substantially the same as the description for the corresponding component in another figure. Further, a statement that a particular embodiment (e.g., as shown in a figure herein) does not have a particular feature or component does not mean, unless expressly stated, that such embodiment is not capable of having such feature or component. For example, for purposes of present or future claims herein, a feature or component that is described as not being included in an example embodiment shown in one or more particular drawings is capable of being included in one or more claims that correspond to such one or more particular drawings herein. The numbering scheme for the various components in the figures herein is such that each component is a three digit number and corresponding components in other figures have the identical last two digits.

Example embodiments of systems for testing GFCI breakers will be described more fully hereinafter with reference to the accompanying drawings, in which example embodiments of systems for testing GFCI breakers are shown. Systems for testing GFCI breakers may, however, be embodied in many different forms and should not be construed as limited to the example embodiments set forth herein. Rather, these example embodiments are provided so that this disclosure will be thorough and complete, and will fully convey the scope of systems for testing GFCI breakers to those of ordinary skill in the art. Like, but not necessarily the same, elements (also sometimes called components) in the various figures are denoted by like reference numerals for consistency.

Terms such as “first”, “second”, “top”, “bottom”, “side”, “width”, “length”, “radius”, “distal”, “proximal”, “inner”, and “outer” are used merely to distinguish one component (or part of a component or state of a component) from another. Such terms are not meant to denote a preference or a particular orientation, and are not meant to limit embodiments of systems for testing GFCI breakers. In the following detailed description of the example embodiments, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

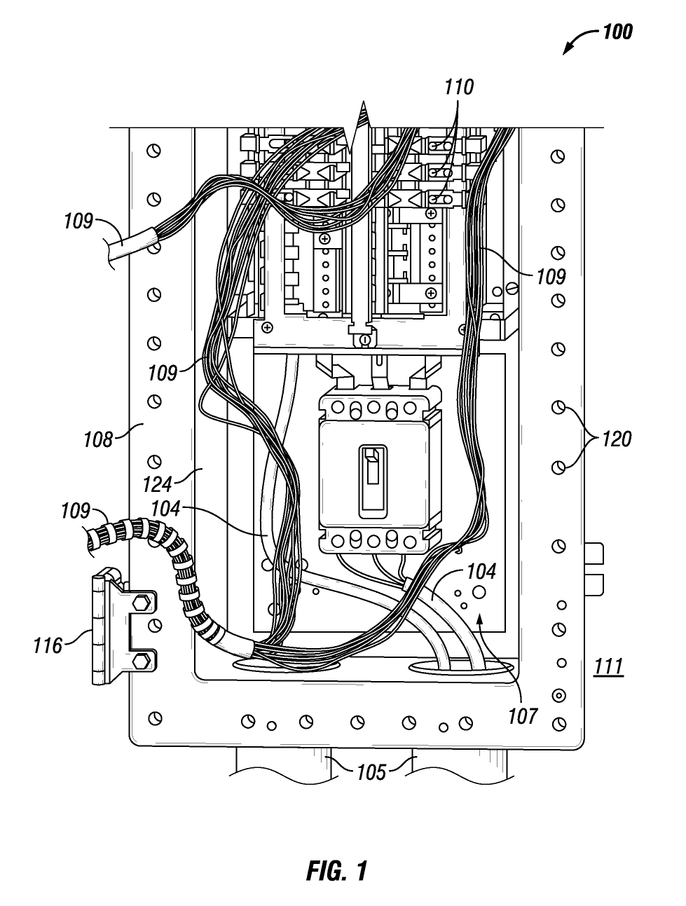

FIG. 1 shows a front view of an enclosure in which a number of GFCI breakers are disposed. Referring now to FIG. 1, the enclosure 100 is in an open position (i.e., the enclosure cover (not shown) is separated from the enclosure body 124). The enclosure 100 is located in an ambient environment 111 (e.g., outdoors, a hazardous environment). The enclosure cover can be secured to the enclosure body 124 by a number of fastening devices (not shown) disposed within a number of apertures 120 around the perimeter of an enclosure engagement surface (not shown) (also called a flange) of the enclosure cover and around the perimeter of the enclosure engagement surface 108 (also called a flange 108) of the enclosure body 124.

When the enclosure cover and the enclosure body 124 are in the closed position relative to each other, the enclosure engagement surface 108 of the enclosure body 124 abuts against the enclosure engagement surface of the enclosure cover. When the enclosure 100 is an explosion-proof enclosure, as in this case, a flame path is formed between the enclosure engagement surface 108 of the enclosure body 124 and the enclosure engagement surface of the enclosure cover. The enclosure body forms a cavity 107 inside of which one or more components (e.g., GFCI breakers 110, electrical wires 109) are disposed. When the enclosure cover and the enclosure body 124 are in the closed position relative to each other, then the cavity 107 is substantially enclosed.

A fastening device may be one or more of a number of fastening devices, including but not limited to a bolt (which may be coupled with a nut), a screw (which may be coupled with a nut), and a clamp. In addition, one or more optional hinges 116 can be secured to one side of the enclosure cover and a corresponding side of the enclosure body 124 so that, when all of the fastening devices are removed, as shown in FIG. 1, the enclosure cover may swing outward (i.e., an open position) from the enclosure body 124 using the one or more hinges 116. In one or more example embodiments, there are no hinges, and the enclosure cover can be completely separated from the enclosure body 124 when all of the fastening devices are removed.

The enclosure cover and the enclosure body 124 may be made of any suitable material, including metal (e.g., alloy, stainless steel), plastic, some other material, or any combination thereof. The enclosure cover and the enclosure body 124 may be made of the same material or different materials. In one or more example embodiments, on the end of the enclosure body 124 opposite the enclosure cover, one or more mounting brackets (hidden from view) are affixed to the exterior of the enclosure body 124 to facilitate mounting the enclosure 100. Using the mounting brackets, the enclosure 100 may be mounted to one or more of a number of surfaces and/or elements, including but not limited to a wall, a control cabinet, a cement block, an I-beam, and a U-bracket.

There can be one or more conduits 105 that are coupled to a wall of the enclosure body 124 of the enclosure 100. Each conduit 105 can have one or more electrical cables 104 disposed therein, where each electrical cable 104 includes one or more electrical wires 109. The electrical wires 109 at one end of an electrical cable 104 can be electrically coupled to one or more devices (e.g., an electrical device, electrical load, a GFCI breaker 110) disposed within the enclosure 100.

As stated above, if the enclosure 100 is an explosion-proof enclosure, certain applicable industry standards must be met. For example, in order to maintain a suitable flame path between the flange of the enclosure cover and the flange 108 of the enclosure body 124, all of the fastening devices must be properly engineered, machined, applied, and tightened within all of the apertures 120. If one or more of the fastening devices is missing and/or if one or more of the fastening devices is not tightened properly (e.g., is tightened to the proper torque), then the flame path may not be compliant with applicable safety standards. This can lead to catastrophic results.

Because some enclosures, such as the enclosure 100 of FIG. 1, have so many fastening devices (in this case, over 30), it can be extremely time-consuming to remove all of the fastening devices to open the enclosure 100, access the cavity 107, and properly re-couple all of the fastening devices to return the enclosure 100 to a closed state. Also, as stated above, certain devices (e.g., GFCI breakers 110) that are located inside the cavity 107 of the enclosure 100 must be tested periodically to ensure that those devices are operating properly. If these tests are not performed on these devices within a prescribed period of time relative to the most recent test, applicable standards and/or regulations are violated. The standards and/or regulations for such devices are designed to promote safety, and so a violation of these standards and/or regulations can result in significant damage.

However, regardless of whether it is easy or difficult to access one or more GFCIs, the current tests performed on a GFCI are incomplete. Specifically, current tests that are performed on GFCIs use only a high current level that is known to exceed the ground current threshold of a GFCI. As stated above, the problem is that a GFCI can have any of a number of thresholds for ground current (also called, for example, a trip point or a trip setting). For example, one GFCI can have a current threshold of 5 mA for personnel safety, while another GFCI can have a ground current threshold of 30 mA for equipment (e.g., heat tracing) safety. In any case, regardless of the ground current threshold of a GFCI, current testing methods fail to capture the level of ground fault current that actually trips a GFCI. Instead, a ground fault current that is sufficiently above the trip setting of a GFCI is used merely to verify that the GFCI trips when the ground fault current exceeds the trip setting.

Alternatively, in some cases a single GFCI can have multiple thresholds for ground current. For example, a single GFCI can have a ground current threshold of 5 mA for personnel safety, as well as a ground current threshold of 30 mA for equipment (e.g., heat tracing) safety. Thus, when a GFCI is tested today, there is no distinction as to whether the GFCI properly operates at all of the multiple ground current thresholds.

Using example embodiments, several benefits are derived. First, verification can be achieved as to the proper operation of the ground current threshold (or, in cases where the GFCI has multiple ground current thresholds, each ground current threshold) of a GFCI in each test performed on the GFCI. Second, the value of each ground current threshold of a GFCI can be compared against the nameplate value to determine if the GFCI is set and/or operating properly for each ground current threshold. Third, the value of each ground current threshold of a GFCI can be tracked and evaluated over time to see if a particular ground current threshold is changing, representing a deterioration and potential failure of the GFCI.

Further, example embodiments can be mounted on the outside of the enclosure 100 so that the GFCI breakers 110 can be tested without a user having to access the cavity 107 of the enclosure 100. Alternatively, a user can communicate with example embodiments wirelessly, while example embodiments are located inside an enclosure, so that the GFCI breakers 110 can be tested without a user having to access the cavity 107 of the enclosure 100. In the current art, a combination of at least two switches (not shown) and a pushbutton (also not shown) is mounted on the enclosure cover and is electrically coupled, using the various electrical wires 109, to each of the GFCI breakers 110 disposed in the cavity 107 of the enclosure 100.

As a result, a tremendous amount of time and expense is allocated to installing the testing system currently used in the art. As FIG. 1 shows, a large number of electrical wires 109 are disposed in the cavity 107 and terminated at various locations throughout the enclosure 100. It takes a user (e.g., an electrician) hours to perform this wiring, and the chances of crossing wires and having to rewire are high. Also, each switch is highly specialized and relatively expensive. At least one switch is a selector switch used to select a particular GFCI breaker, and so must have at least as many positions as there are GFCI breakers 110 in the cavity 107. The common switch for this purpose has 21 selection positions.

The other switch currently used in the art is a multi-position switch that is used to select one or more particular GFCI breakers 110. Another problem with the switch/pushbutton combination currently used in the art is that multiple (at least two) penetrations must be made through the enclosure cover. If the enclosure 100 is an explosion-proof enclosure, then each penetration has a flame path that must be properly engineered and configured so that the enclosure 100 continues to be compliant with applicable industry safety standards. Again, this adds cost and time to ensuring that the switch/pushbutton combination for testing the GFCI breakers is properly integrated into the enclosure 100.

Alternatively (and most commonly), a mechanical plunger can penetrate the enclosure for each GFCI circuit. To test, each mechanical plunger is depressed and mechanically contacts/depresses the test button built into the GFCI breaker. This is also cost prohibitive and can, for certain enclosures (e.g., explosion-proof enclosures) create a large number of penetrations (e.g., flame paths) in the enclosure and the mechanical mechanisms that may contain flame paths. Again, these testing systems currently used in the art do not test for any ground current threshold values of a GFCI. Rather, current tests merely test using a high ground fault current that substantially exceeds the ground current threshold of the GFCI.

By contrast, example embodiments include a testing system that is significantly more easily wired and integrated with the GFCIs. Further, the testing system of example embodiments can be automated with respect to testing, recording results, evaluating results (both in single tests and over time), reporting results, and resolving problems with a defective or failed GFCI. Further, example embodiments can be utilized with no more than one penetration through the enclosure cover, and the amount of wiring and mechanical parts is substantially reduced compared to the switch/pushbutton combination currently used in the art. Further, example embodiments have significantly fewer (if any) mechanical mechanisms that contain flame paths. In addition, as discussed above, current testing systems only test whether a GFCI breaker 110 trips, where example testing systems determine the actual value of the ground current threshold of a GFCI breaker 110.

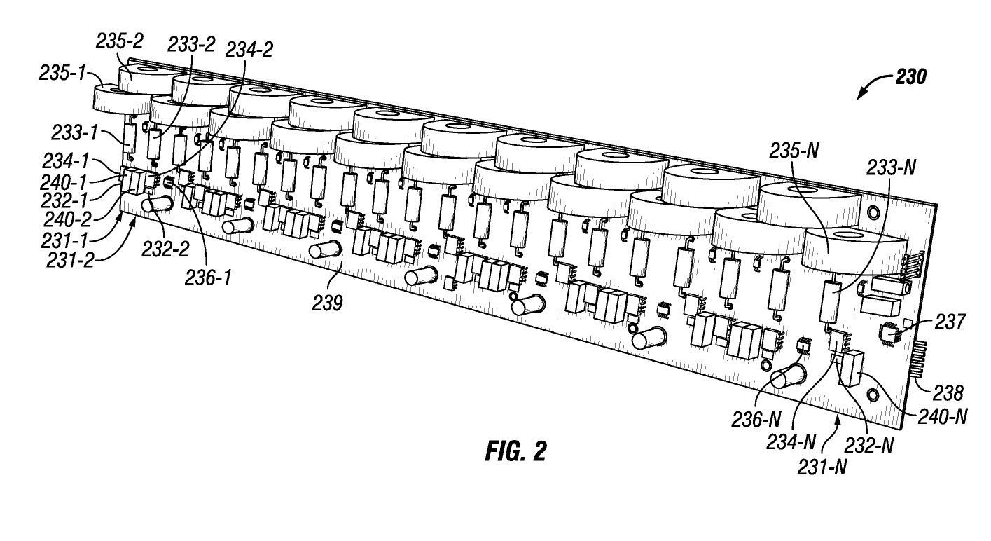

An example of how example embodiments can be integrated into a GFCI scheme is shown in FIG. 2, which shows a testing circuit assembly 230 in accordance with certain example embodiments. Referring to FIGS. 1 and 2, the testing circuit assembly 230 can perform one or more functions. For example, the testing circuit assembly 230 can have one or more variable resistive loads 240 (e.g., variable resistive load 240-1, variable resistive load 240-2, variable resistive load 240-N. Each variable resistive load 240 can be made of one or more of a number of components, including but not limited to a triac, an opto-triac, an AC switch, a phase control device, and a potentiometer. In such a case, each variable resistive load 240 can drive a varying current.

As another example, the testing circuit assembly 230 can create a load-to-Earth ground, which creates a short circuit. In such a case, when a variable resistive load 240 is part of the load-to-Earth ground, some number (in this case, 21) of GFCI breakers 110 can be electrically coupled to the testing circuit assembly 230, where each GFCI breaker 110 is individually coupled to its own testing circuit 231 (e.g., testing circuit 231-1, testing circuit 231-2, testing circuit 231-N). Thus, when the testing circuit assembly 230 creates a load-to-Earth ground, one or more of the GFCI breakers 110 can be tested, and changing the variable resistive load 240 varies the current, which simulates a ground fault, that flows to the Earth ground.

The testing circuit assembly 230 can include one or more of a number of components. For example, the sensing circuit assembly 230 can include a plug connector 238 to allow the sensing circuit assembly 230 (or portions thereof) to send and receive signals (e.g., power signals, control signals, data signals, communication signals) with another portion (e.g., a network manager, the user interface assembly 340) of a system. As another example, the sensing circuit assembly 230 can include a main controller 237. In such a case, the main controller 237 can control the various local controllers 234 (e.g., local controller 234-1, local controller 234-2, local controller 234-N) of the testing circuits 231, all described below. The main controller 237 can also assume the responsibility of communicating with other portions of the system, including but not limited to a user and a network manager.

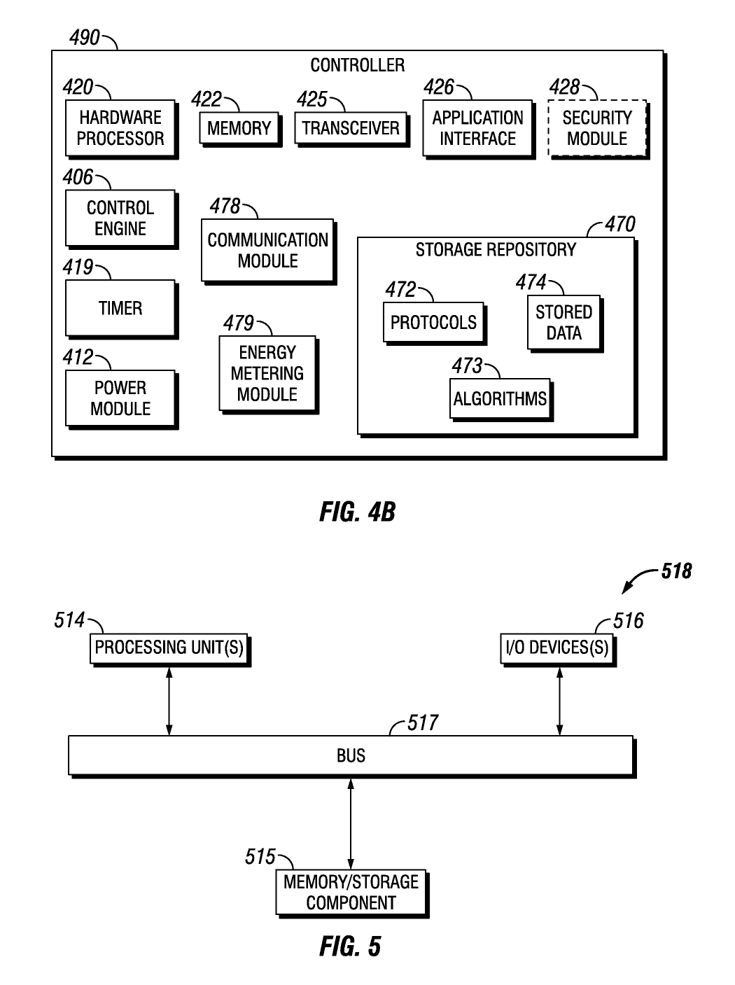

In certain example embodiments, the main controller 237 can include one or more of a number of components. Examples of such components can include, but are not limited to, a control engine, a communication module, a real-time clock, a power module, an energy measurement module, a storage repository, a hardware processor, a memory, a transceiver, an application interface, and a security module. More details about the optional main controller 237 are described below with respect to FIGS. 4A and 4B. The main controller 237 can correspond to a computer system 518 as described below with regard to FIG. 5.

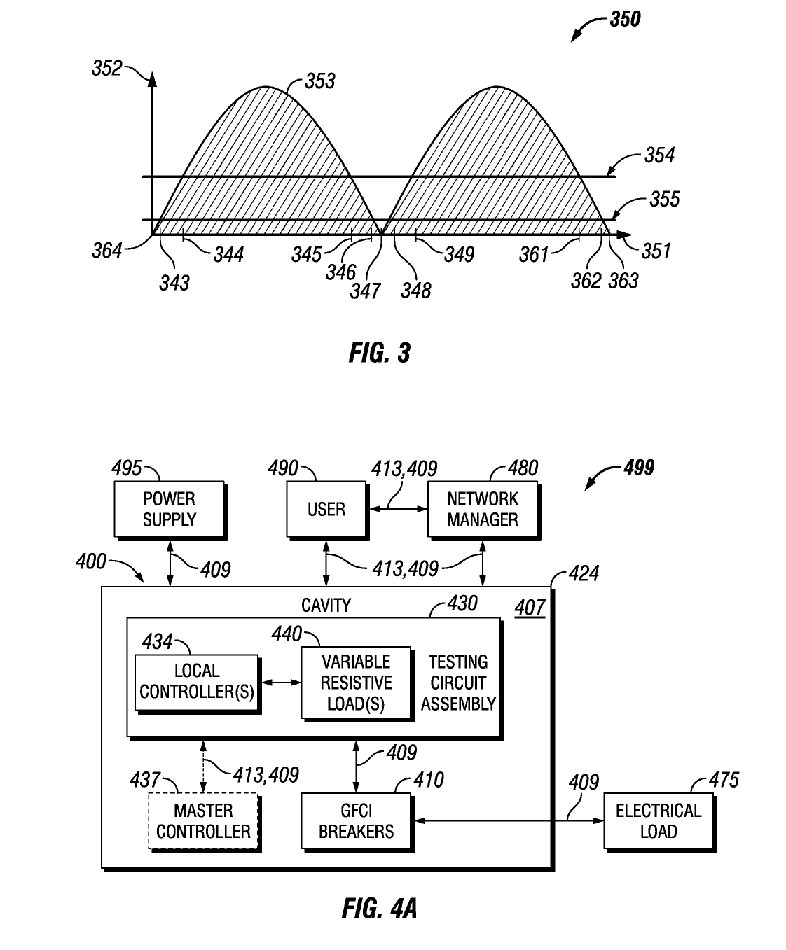

In certain example embodiments, the main controller 237 adjusts the various variable resistive loads 240. Alternatively, the main controller 237 controls the local controllers 234, which adjust the various variable resistive loads 240. to operate (e.g., based on the user's instructions, automatically according to a schedule set forth in software of the local controller 234). A variable resistive load 240 can be adjusted in one or more of a number of ways. For example, as shown in FIG. 3 below, a variable resistive load 240 can be continually adjusted over a range of values. As another example, a variable resistive load 240 can be adjusted by discrete values over a range of values. As yet another example, a variable resistive load 240 can be adjusted randomly over a range of values.

When a variable resistive load 240 is connected to an Earth ground of a circuit for a GFCI breaker 110, the variable resistive load 240 can act like a variable impedance. As the variable resistive load 240 changes value, the amount of current that flows through the variable resistive load 240 to the Earth ground changes. For example, as the resistance of the variable resistive load 240 increases, the level of current that flows through the variable resistive load 240 to the Earth ground decreases. For a given resistance of a variable resistive load 240, an equivalent to a ground fault current can be determined. Put in a different way, when the variable resistive load 240 includes phase control, the angle (e.g., between 0° and) 180° where a trip of the GFCI breaker 110 occurs corresponds to a trip current level.

Using the results of testing fault currents on each GFCI breaker 110, the main controller 237 can perform a number of prognostic, diagnostic, and other analytical functions with respect to the GFCI breakers 110. For example, the main controller 237 can measure, store, analyze, and report (e.g., automatically, based on user instruction) various information (e.g., amounts of ground fault current required to trip circuit during testing, number of operations of the GFCI breaker 110, age of the GFCI breaker, amount of ground fault current that tripped GFCI breaker outside of a test) over time associated with each GFCI breaker 110.

The main controller 237 can use this data, as well as other data measured, stored, and analyzed by other main controllers 237 from other systems, to determine a number of factors associated with a particular GFCI breaker 110, including but not limited to the expected life of the GFCI breaker 110, the current trip points of the GFCI breaker 110, and when to schedule maintenance on the GFCI breaker 110. In some cases, the main controller 237 can interact with other systems to perform a number of functions. For example, the main controller 237 can order a replacement GFCI breaker 110 when an existing one has failed or is about to fail. As another example, the main controller 237 can schedule an electrician to replace or maintain a GFCI breaker 110. As yet another example, the main controller 237 can automatically compile and submit compliance reports with appropriate entities (e.g., regulatory bodies) with respect to GFCI breaker testing.

As yet another example, the testing circuit assembly 230 can include multiple testing circuits 231 (e.g., testing circuit 231-1, testing circuit 231-2, testing circuit 231-N) disposed on a circuit board 239. Each testing circuit 231 can include one or more of a number of components, including but not limited to the local controller 234 (e.g., local controller 234-1, local controller 234-2, local controller 234-N), a resistor 233 (e.g., resistor 233-1, resistor 233-2, resistor 233-N), a current transformer 235 (e.g., current transformer 235-1, current transformer 235-2, current transformer 235-N), a variable resistive loads 240, and an integrated circuit 236 (e.g., integrated circuit 236-2, integrated circuit 236-N). A local controller 234 can include one or more of the components described above with respect to the main controller 237. More details about the local controller 234 are described below with respect to FIGS. 4A and 4B. A local controller 234 can correspond to a computer system 518 as described below with regard to FIG. 5.

FIG. 3 shows a graph 350 of testing a GFCI breaker 110 in accordance with certain example embodiments. Referring to FIGS. 1-3, the graph 350 has a vertical scale 352 (in this case, current) and a horizontal scale 351 (e.g., an angle, time). The graph 350 shows a plot of a full cycle of power 353 (rectified for positive values). The power 353 in this case can be current. The power 353 starts at a zero value at angle 364 (or, in some cases, time 364) and gradually increases as the angle 351 (or time 351) increases. At angle 343 (or time 343), which corresponds to fault current 355 (e.g., 5 mA), the GFCI breaker 110 trips for personnel safety.

As the angle 351 (or time 351) continues to increase, at angle 344 (or time 344), which corresponds to fault current 354 (e.g., 30 mA), the GFCI breaker 110 trips for heat tracing. The power 353 continues to rise until it peaks (roughly corresponding to an angle of) 90°, and then it decreases to complete the first half-cycle. As the power 353 decreases, it passes through angle 345 (or time 345), which corresponds to fault current 354, and angle 346 (or time 346), which corresponds to fault current 355. When the power 353 reaches an angle 347 of 180° (or time 347), the power 353 is at zero, and the second half of the cycle begins. Specifically, at angle 348 (or time 348) corresponds to fault current 355, angle 349 (or time 349) corresponds to fault current 354, angle 361 (or time 361) corresponds to fault current 354, and angle 362 (or time 362) corresponds to fault current 355. The second half of the cycle ends at an angle 363 of 360° (or time 363), which corresponds to no power 353.

The graph 350 of FIG. 3 can represent test results of a single GFCI breaker 110 with multiple (in this case, two) trip settings of approximately 5 mA and 30 mA. Alternatively, the graph 350 of FIG. 3 can represent test results of two different GFCI breakers, where one GFCI breaker has a trip setting of approximately 5 mA, and the other GFCI breaker has a trip setting of approximately 30 mA.

FIGS. 4A and 4B show a diagram of a system 499 that includes a testing circuit assembly 430 for one or more GFCI breakers 410 in accordance with certain example embodiments. Specifically, FIG. 4A shows the system 499 that includes a testing circuit assembly 430 within an enclosure 400, and FIG. 4B shows a detailed system diagram of a local controller 434 of the testing circuit assembly 430. Referring to FIGS. 1-4B, the system 499 can include one or more components. For example, as shown in FIGS. 4A and 4B, the system 499 can include a user 490, a network manager 480, a power supply 495, an electrical load 475, and the enclosure 400. The enclosure 400 can include a testing circuit assembly 430 (which includes the local controller 434 and one or more variable resistive loads 440), one or more GFCI breakers, and an optional master controller 437.

FIG. 4B shows a system diagram of a local controller 434 for a testing circuit assembly 430 in accordance with certain example embodiments. The local controller 434 can include one or more of a number of components. Such components, can include, but are not limited to, a control engine 406, a communication module 478, a timer 419, an energy metering module 479, a power module 412, a storage repository 470, a hardware processor 420, a memory 422, a transceiver 425, an application interface 426, and, optionally, a security module 428.

The components shown in FIGS. 4A and 4B are not exhaustive, and in some embodiments, one or more of the components shown in FIGS. 4A and 4B may not be included in an example enclosure 400 or, more specifically, an example testing circuit assembly 430. Further, one or more components shown in FIGS. 4A and 4B can be rearranged. For example, the energy metering module 479 can be separate from the local controller 434 of FIG. 4B. As another example, one or more variable resistive loads 440 of FIG. 4A can be part of the local controller 434 of FIG. 4B. Any component of the example local controller 434, as with the example testing circuit assembly 430, can be discrete or combined with one or more other components of the local controller 434 (or testing circuit assembly 430).

Each of the variable resistive loads 440 of the testing circuit assembly 430 can be substantially similar to the variable resistive loads 240 described above with respect to FIG. 2. A variable resistive load 440 can include one or more of a number of discrete components (e.g., varister, switch, capacitor, integrated circuit, triac, opto-triac, phase control device, potentiometer) and/or one or more hardware components. As stated above, each variable resistive load 440 is adjusted by a local controller 434 and/or the master controller 437 to drive a varying current through a GFCI breaker 410.

A user 490 may be any person that interacts with the electrical load 475, the enclosure 400, the GFCI breakers 410, and/or other devices that use example embodiments. Examples of a user 490 are provided above. The user 490 can use a user system (not shown), which may include a display (e.g., a GUI). The user 490 interacts with (e.g., sends data to, receives data from) the local controller 434 (and/or other portion of the testing circuit assembly 430) of the enclosure 400 via the application interface 426 (described below), which may involve the use of using signal transfer links 413 and/or electrical wires 409. The user 490 can also interact with the network manager 480, the power supply 480, the GFCI breakers 410, the master controller 437, and/or the electrical load 475 using signal transfer links 413 and/or electrical wires 409.

Each signal transfer link 413 and each electrical wire 409 can include wired (e.g., Class 1 electrical cables, Class 2 electrical cables, electrical connectors, electrical conductors, electrical traces on a circuit board, power line carrier, DALI, RS485) and/or wireless (e.g., Wi-Fi, visible light communication, cellular networking, Bluetooth, WirelessHART, ISA100, inductive power transfer) technology. For example, a signal transfer link 413 can be (or include) one or more electrical conductors (e.g., electrical wires 409) that are coupled to a local controller 434 and one or more variable resistor loads 440 of the testing circuit assembly 430. A signal transfer link 413 can transmit signals (e.g., communication signals, control signals, data) between the enclosure 400, the user 490, the network manager 480, and/or the electrical load 475. Similarly, an electrical wire 409 can transmit power between the enclosure 400, the user 490, the network manager 480, and/or the electrical load 475. One or more signal transfer links 413 and/or one or more electrical wires 409 can also transmit signals and power, respectively, between components (e.g., local controller 434, variable resistive load 440) within and/or on the enclosure body 424 of the enclosure 400.

In certain example embodiments, the power supply 495 provides power (also called primary power herein), using electrical wires 409, to one or more components (e.g., the testing circuit assembly 430) of the enclosure 400 and, by extension, the electrical load 475. The power supply 495 can include one or more of a number of single or multiple discrete components (e.g., transistor, diode, resistor), and/or a microprocessor. The power supply 495 can include a printed circuit board, upon which the microprocessor and/or one or more discrete components are positioned.

The power supply 495 can include one or more components (e.g., a transformer, a diode bridge, an inverter, a constant voltage-constant current (CV-CC) converter, a generic converter) that receives power (for example, through one or more electrical wires 409) from a power source (not shown in FIG. 4A) and generates power of a type (e.g., alternating current, direct current) and level (e.g., 12V, 24V, 120V) that can be used by the electrical load 475 and one or more components of the enclosure 400. In addition, or in the alternative, the power supply 495 can be a source of power in itself. For example, the power supply 495 can be a battery, a localized photovoltaic power system, or some other source of independent power.

The network manager 480 is a device or component that can communicate with the testing circuit assembly 430 (including the local controllers 434 and the optional master controller 437). For example, the network manager 480 can send instructions to the local controller 434 of the testing circuit assembly 430 as to when certain variable resistive loads 440 should be operated (e.g., adjusted upward, adjusted downward). As another example, the network manager 480 can receive data (e.g., run time, current flow) associated with the testing of each GFCI breaker 410 to determine when maintenance should be performed on a GFCI breaker 410 and/or when a GFCI breaker 410 should be replaced.

The electrical load 475 of the system 499 can be one or more of a number of electrical devices that operate using the primary power supplied by the power supply 495 and that are fed by a GFCI breaker 410. Examples of electrical devices that can be included in the electrical load 475 include, but are not limited to, a light source, a motor, a heating element, an electrical outlet, a control panel, and a control device. The electrical load 475 can operate using fixed or variable power.

The user 490, the network manager 480, the GFCI breakers 410, one or more other local controllers 434, the master controller 437, and/or the electrical load 475 can interact with a local controller 434 of the testing circuit assembly 430 using the application interface 426 in accordance with one or more example embodiments. Specifically, the application interface 426 of a local controller 434 receives data (e.g., information, communications, instructions, updates to firmware) from and sends data (e.g., information, communications, instructions) to the user 490, the network manager 480, the GFCI breakers 410, one or more other local controllers 434, the master controller 437, and/or the electrical load 475. The user 490, the network manager 480, the GFCI breakers 410, one or more other local controllers 434, the master controller 437, and/or the electrical load 475 can include an interface to receive data from and send data to a local controller 434 in certain example embodiments. Examples of such an interface can include, but are not limited to, a graphical user interface, a touchscreen, an application programming interface, a keyboard, a monitor, a mouse, a web service, a data protocol adapter, some other hardware and/or software, or any suitable combination thereof.

The local controller 434, the user 490, the network manager 480, the GFCI breakers 410, the master controller 437, and/or the electrical load 475 can use their own system or share a system in certain example embodiments. Such a system can be, or contain a form of, an Internet-based or an intranet-based computer system that is capable of communicating with various software. A computer system includes any type of computing device and/or communication device, including but not limited to the local controller 434. Examples of such a system can include, but are not limited to, a desktop computer with Local Area Network (LAN), Wide Area Network (WAN), Internet or intranet access, a laptop computer with LAN, WAN, Internet or intranet access, a smart phone, a server, a server farm, an android device (or equivalent), a tablet, smartphones, and a personal digital assistant (PDA). Such a system can correspond to a computer system as described above with regard to FIG. 5.

Further, as discussed above, such a system can have corresponding software (e.g., user software, local controller software, network manager software). The software can execute on the same or a separate device (e.g., a server, mainframe, desktop personal computer (PC), laptop, PDA, television, cable box, satellite box, kiosk, telephone, mobile phone, or other computing devices) and can be coupled by the communication network (e.g., Internet, Intranet, Extranet, LAN, WAN, or other network communication methods) and/or communication channels, with wire and/or wireless segments according to some example embodiments. The software of one system can be a part of, or operate separately but in conjunction with, the software of another system within the system 499.

As discussed above, the enclosure 400 can include an enclosure body 424. The enclosure body 424 can include at least one wall that forms a cavity 407. In some cases, the enclosure body 424, when coupled to an enclosure cover (not shown), can be designed to comply with any applicable standards so that the enclosure 400 (including portions thereof, such as the testing circuit assembly 430) can be located in a particular environment (e.g., a hazardous environment). For example, if the enclosure 400 is located in an explosive environment, the enclosure 400 can be explosion-proof. According to applicable industry standards, an explosion-proof enclosure is an enclosure that is configured to contain an explosion that originates inside, or can propagate through, the enclosure.

The enclosure body 424 of the enclosure 400 can be used to house one or more components of the testing circuit assembly 430, including one or more components of the local controller 434. For example, as shown in FIGS. 4A and 4B, the local controller 434 (which in this case includes the control engine 406, the communication module 478, the timer 419, the energy metering module 479, the power module 412, the storage repository 470, the hardware processor 420, the memory 422, the transceiver 425, the application interface 426, and the optional security module 428), the remainder of the testing circuit assembly 430 (e.g., the variable resistive loads 440), the GFCI breakers 410, and the master controller 437 are disposed in the cavity 407 formed, at least in part, by the enclosure body 424. In alternative embodiments, any one or more of these or other components of the enclosure 400 can be disposed on the enclosure body 424 (or other part of the enclosure 400, such as the enclosure cover) and/or remotely from the enclosure 400.

The storage repository 470 can be a persistent storage device (or set of devices) that stores software and data used to assist the local controller 434 in communicating with the user 490, the network manager 480, the GFCI breakers 410, the master controller 437, and/or the electrical load 475 within the system 499. In one or more example embodiments, the storage repository 470 stores one or more protocols 472, algorithms 473, and stored data 474. The protocols 472 can be any procedures (e.g., a series of method steps) and/or other similar operational procedures that the control engine 406 of the local controller 434 follows based on certain conditions at a point in time. The protocols 472 can include any of a number of communication protocols that are used to send and/or receive data between the local controller 434 and the user 490, the network manager 480, the GFCI breakers 410, the master controller 437, and the electrical load 475.

A protocol 472 can be used for wired and/or wireless communication. Examples of a protocol 472 can include, but are not limited to, Modbus, profibus, Ethernet, and fiberoptic. One or more of the protocols 472 can be a time-synchronized communication protocol. Examples of such time-synchronized protocols can include, but are not limited to, a highway addressable remote transducer (HART) protocol, a wirelessHART protocol, and an International Society of Automation (ISA) 100 protocol. In this way, one or more of the protocols 472 can provide a layer of security to the data transferred within the system 499.

The algorithms 473 can be any formulas, logic steps, mathematical models, and/or other suitable means of manipulating and/or processing data. One or more algorithms 473 can be used for a particular protocol 472. For example, a protocol 472 can call for measuring (using the energy metering module 479), storing (using the stored data 474 in the storage repository 470), and evaluating (using an algorithm 473) the current delivered to a particular GFCI breaker 410 at a particular point in time. The control engine 406 can be configured to modify one or more algorithms 473, for example, by evaluating output of a previous version of an algorithm 473 relative to actual results.

As discussed above, a local controller 434 controls one or more of the variable resistive loads 440 in certain example embodiments. A local controller 434 can base its control of a variable resistive load 440 using a protocol 472, an algorithm 473, and or stored data 474. For example, a protocol 472 can dictate the length of time (e.g., measured by the timer 419) where the power supply 495 provides primary power to one or more of the GFCI breakers 410. As another example, an algorithm 473 can be used, in conjunction with measurements made by one or more of the energy metering module 479, to determine how one or more variable resistive loads 440 are adjusted while testing a GFCI breaker 410.

Stored data 474 can be any data associated with the enclosure 400, including the testing circuit assembly 430, any measurements taken by the energy metering module 479, time measured by the timer 419, threshold values, tripping points of the GFCI breakers 410, results of previously run or calculated algorithms 473, and/or any other suitable data. Such data can be any type of data, including but not limited to historical data for the testing circuit assembly 430 (including any components thereof, such as the variable resistive loads 440), historical data for the enclosure 400, calculations, measurements taken by the energy metering module 479, nameplate information for the GFCI breakers 410, and user preferences. The stored data 474 can be associated with some measurement of time derived, for example, from the timer 419.

Examples of a storage repository 470 can include, but are not limited to, a database (or a number of databases), a file system, a hard drive, flash memory, some other form of solid state data storage, or any suitable combination thereof. The storage repository 470 can be located on multiple physical machines, each storing all or a portion of the protocols 472, the algorithms 473, and/or the stored data 474 according to some example embodiments. Each storage unit or device can be physically located in the same or in a different geographic location.

The storage repository 470 can be operatively connected to the control engine 406. In one or more example embodiments, the control engine 406 includes functionality to communicate with the user 490, the network manager 480, the GFCI breakers 410, the master controller 437, and/or the electrical load 475 in the system 499. More specifically, the control engine 406 can send information to and/or receives information from the storage repository 470 in order to communicate with the user 490, the network manager 480, the GFCI breakers 410, the master controller 437, and/or the electrical load 475. As discussed below, the storage repository 470 can also be operatively connected to the communication module 478 in certain example embodiments.

In certain example embodiments, the control engine 406 of the local controller 434 controls the operation of one or more components (e.g., the communication module 478, the timer 419, the transceiver 425) of the local controller 434. For example, the control engine 406 can activate the communication module 478 when the communication module 478 is in “sleep” mode and when the communication module 478 is needed to send data received from another component (e.g., the network manager 480, the user 490) in the system 499.

As another example, the control engine 406 can acquire the current time using the timer 419. The timer 419 can enable the local controller 434 to control the one or more other components of the testing circuit assembly 430 (e.g., one or more variable resistive loads 440) even when the local controller 434 has no communication with other components (e.g., the network manager 480, the user 490, the master controller 437). As yet another example, the control engine 406 can direct the energy metering module 479 to measure the variable current flowing through a GFCI breaker 410. In some cases, the control engine 406 of a local controller 434 can control the resistance of each variable resistive load 440.

The control engine 406 can use any of the protocols 472 and/or algorithms 473 stored in the storage repository 470 to determine when to change the resistance of one or more variable resistive loads 440 and/or when to allow power from the power supply 495 to flow through a particular variable resistive load 440 to a GFCI breaker 410. As a specific example, the control engine 406 can follow a protocol 472 by measuring (using the energy metering module 479), storing (as stored data 474 in the storage repository 470), and evaluating, using an algorithm 473, the current delivered to a GFCI breaker 410 and what level of current coincides with tripping the GFCI breaker 410. As another specific example, the control engine 406 can determine, based on measurements made by the energy metering module 479, whether a particular GFCI breaker 410 has failed or is failing.

The control engine 406 can generate an alarm when an operating parameter (e.g., total number of operating hours, number of consecutive operating hours, failure of a GFCI breaker 410 to trip at a rated current), exceeds or falls below a threshold value, indicating possible present or future failure of the testing circuit assembly 430 (or component thereof) or a GFCI breaker 410. The control engine 406 can further measure (using the energy metering module 479) and analyze the magnitude and number of surges that a GFCI breaker 410 is subjected to over time.

In some cases, a local controller 434 can test, measure, and store the one or more tripping points of a GFCI breaker 410. Using this historical information, the local controller 434 can determine whether there are indications that the GFCI breaker 410 is failing or has failed. The local controller 434 can communicate these evaluations (e.g., to the user 490, to the network manager 480) so that appropriate action (e.g., repair the GFCI breaker 410, replace the GFCI breaker 410) can be taken.

Using one or more algorithms 473, the control engine 406 can predict the expected useful life of one or more GFCI breakers 410 based on stored data 474, a protocol 472, one or more threshold values, and/or some other factor. The control engine 406 can also measure (using the energy metering module 479) and analyze the efficiency of the testing circuit assembly 430 (or component thereof) over time. An alarm can be generated by the control engine 406 when the efficiency of the testing circuit assembly 430 (or component thereof) and/or a GFCI circuit 410 falls below a threshold value, indicating failure of the testing circuit assembly 430 (or component thereof, such as a variable resistive load 440) and/or the GFCI circuit 410.

The control engine 406 can provide power, control, communication, and/or other similar signals to the user 490, the network manager 480, the variable resistive loads 440, the GFCI breakers 410, the master controller 437, and/or the electrical load 475. Similarly, the control engine 406 can receive power, control, communication, and/or other similar signals from the user 490, the network manager 480, the variable resistive loads 440, the GFCI breakers 410, the master controller 437, and/or the electrical load 475. The control engine 406 can control each variable resistive load 440 automatically (for example, based on one or more algorithms 473 stored in the control engine 406) and/or based on power, control, communication, and/or other similar signals received from another component (e.g., the user 490, the master controller 437) through a signal transfer link 413 and/or an electrical wire 409. The control engine 406 may include a printed circuit board, upon which the hardware processor 420 and/or one or more discrete components of the local controller 434 are positioned.

In certain embodiments, the control engine 406 of the local controller 434 can communicate with one or more components of a system external to the system 499 in furtherance of optimizing the performance of the testing circuit assembly 430 (or portions thereof). For example, the control engine 406 can interact with an inventory management system by ordering a component (e.g., a variable resistive load 440) of the testing circuit assembly 430 to replace a component of the testing circuit assembly 430 that the control engine 406 has determined to fail or be failing. As another example, the control engine 406 can interact with a workforce scheduling system by scheduling a maintenance crew to repair or replace a GFCI breaker 410 when the control engine 406 determines that the GFCI breaker 410 requires maintenance or replacement. In this way, the local controller 434 is capable of performing a number of functions beyond what could reasonably be considered a routine task.

In certain example embodiments, the control engine 406 can include an interface that enables the control engine 406 to communicate with one or more components (e.g., a power supply 495, the electrical load 475) of the system 499. For example, if a power supply 495 operates under IEC Standard 62386, then the power supply 495 can have a serial communication interface that transfers data (e.g., stored data 474) measured by the energy metering module 479. In such a case, the control engine 406 can also include a serial interface to enable communication with the power supply 495. Such an interface can operate in conjunction with, or independently of, the protocols 472 used to communicate between the local controller 434 and the user 490, the network manager 480, the variable resistive loads 440, the GFCI breakers 410, the master controller 437, and/or the electrical load 475.

The control engine 406 (or other components of the local controller 434) can also include one or more hardware components and/or software elements to perform its functions. Such components can include, but are not limited to, a universal asynchronous receiver/transmitter (UART), a serial peripheral interface (SPI), a direct-attached capacity (DAC) storage device, an analog-to-digital converter, an inter-integrated circuit (I2C), and a pulse width modulator (PWM).

The communication module 478 of the local controller 434 determines and implements the communication protocol (e.g., from the protocols 472 of the storage repository 470) that is used when the control engine 406 communicates with (e.g., sends signals to, receives signals from) the user 490, the network manager 480, the variable resistive loads 440, the GFCI breakers 410, the master controller 437, and/or the electrical load 475. In some cases, the communication module 478 accesses the stored data 474 to determine which communication protocol is used to communicate with the user 490, the network manager 480, the variable resistive loads 440, the GFCI breakers 410, the master controller 437, and/or the electrical load 475 associated with the stored data 474. In addition, the communication module 478 can interpret the communication protocol of a communication received by the local controller 434 so that the control engine 406 can interpret the communication.

The communication module 478 can send and receive data between the network manager 480, the user 490, the network manager 480, the variable resistive loads 440, the GFCI breakers 410, the master controller 437, the local controller 434, and/or the electrical load 475. The communication module 478 can send and/or receive data in a given format that follows a particular protocol 472. The control engine 406 can interpret the data packet received from the communication module 478 using the protocol 472 information stored in the storage repository 470. The control engine 406 can also facilitate the data transfer between the network manager 480, the user 490, the network manager 480, the variable resistive loads 440, the GFCI breakers 410, the master controller 437, the local controller 434, and/or the electrical load 475 by converting the data into a format understood by the communication module 478.

The communication module 478 can send data (e.g., protocols 472, algorithms 473, stored data 474, operational information, alarms) directly to and/or retrieve data directly from the storage repository 470. Alternatively, the control engine 406 can facilitate the transfer of data between the communication module 478 and the storage repository 470. The communication module 478 can also provide encryption to data that is sent by the local controller 434 and decryption to data that is received by the local controller 434. The communication module 478 can also provide one or more of a number of other services with respect to data sent from and received by the local controller 434. Such services can include, but are not limited to, data packet routing information and procedures to follow in the event of data interruption.

The timer 419 of the local controller 434 can track clock time, intervals of time, an amount of time, and/or any other measure of time. The timer 419 can also count the number of occurrences of an event (e.g., the number of times a GFCI breaker 410 trips), whether with or without respect to time. Alternatively, the control engine 406 can perform the counting function. The timer 419 is able to track multiple time measurements concurrently. The timer 419 can track time periods based on an instruction received from the control engine 406, based on an instruction received from the user 490, based on an instruction programmed in the software for a local controller 434, based on some other condition or from some other component, or from any combination thereof.

The timer 419 can be configured to track time when there is no power delivered to the local controller 434 (e.g., the power module 412 malfunctions) using, for example, a super capacitor or a battery backup. In such a case, when there is a resumption of power delivery to the local controller 434, the timer 419 can communicate any aspect of time to the local controller 434. In such a case, the timer 419 can include one or more of a number of components (e.g., a super capacitor, an integrated circuit) to perform these functions.

The energy metering module 479 of the local controller 434 measures one or more components of power (e.g., current, voltage, resistance, VARs, watts) at one or more points associated with the testing circuit assembly 430 and/or the GFCI breakers 410. The energy metering module 479 can include any of a number of measuring devices and related devices, including but not limited to a voltmeter, an ammeter, a power meter, an ohmmeter, a current transformer, a resistor, a potential transformer, and electrical wiring. In some cases, the energy metering module 479 can be a resistor that generates a signal if there is current flowing through the resistor and/or a voltage across the resistor. The energy metering module 479 can measure a component of power continuously, periodically, based on the occurrence of an event, based on a command received from the control module 406, and/or based on some other factor.

The power module 412 of the local controller 434 provides power to one or more other components (e.g., timer 419, control engine 406) of the local controller 434. In certain example embodiments, the power module 412 receives power from the power supply 495. The power module 412 can have one or more similarities to the power supply 495. For example, the power module 412 can include one or more of a number of single or multiple discrete components (e.g., transistor, diode, resistor), and/or a microprocessor. The power module 412 may include a printed circuit board, upon which the microprocessor and/or one or more discrete components are positioned. In some cases, the power module 412 can include one or more components that allow the power module 412 to measure one or more elements of power (e.g., voltage, current) that is delivered to and/or sent from the power module 412. Alternatively, the energy metering module 479 can measure such elements of power.

The power module 412 can include one or more components (e.g., a transformer, a diode bridge, an inverter, a converter) that receives power (for example, through an electrical cable) from a source external to the testing circuit assembly 430 and generates power of a type (e.g., AC, DC) and level (e.g., 12V, 24V, 420V) that can be used by the other components of the local controller 434, the master controller 437, and/or the remainder of the testing circuit assembly 430. The power module 412 can use a closed control loop to maintain a preconfigured voltage or current with a tight tolerance at the output. The power module 412 can also protect the rest of the electronics (e.g., hardware processor 420, transceiver 425) in the testing circuit assembly 430 from surges generated in the line.

In addition, or in the alternative, the power module 412 can be a source of power in itself to provide signals to the other components of the local controller 434, the master controller 437, and/or the remainder of the testing circuit assembly 430. For example, the power module 412 can be or include a battery or other form of energy storage device. As another example, the power module 412 can be a localized photovoltaic power system. The power module 412 can also have sufficient isolation in the associated components of the power module 412 (e.g., transformers, opto-couplers, current and voltage limiting devices) so that the power module 412 is certified to provide power to an intrinsically safe circuit.

In certain example embodiments, the power module 412 of the local controller 434 can also provide power and/or control signals, directly or indirectly, to one or more of the variable resistive loads 440 and/or the master controller 437. In such a case, the control engine 406 can direct the power generated by the power module 412 to one or more of the variable resistive loads 440 and/or the master controller 437. In this way, power can be conserved by sending power to one or more of the variable resistive loads 440 and/or the master controller 437 when those devices need power, as determined by the control engine 406. In alternative cases, the control engine 406 directs primary power from the power supply 495 to the power module 412.

The hardware processor 420 of the local controller 434 executes software, algorithms 473, protocols 472, and firmware in accordance with one or more example embodiments. Specifically, the hardware processor 420 can execute software on the control engine 406 or any other portion of the local controller 434, as well as software used by the user 490, the network manager 480, the variable resistive loads 440, the GFCI breakers 410, the master controller 437, and/or the electrical load 475. The hardware processor 420 can be an integrated circuit, a central processing unit, a multi-core processing chip, SoC, a multi-chip module including multiple multi-core processing chips, or other hardware processor in one or more example embodiments. The hardware processor 420 is known by other names, including but not limited to a computer processor, a microprocessor, and a multi-core processor.

In one or more example embodiments, the hardware processor 420 executes software instructions stored in memory 422. The memory 422 includes one or more cache memories, main memory, and/or any other suitable type of memory. The memory 422 can include volatile and/or non-volatile memory. The memory 422 is discretely located within the local controller 434 relative to the hardware processor 420 according to some example embodiments. In certain configurations, the memory 422 can be integrated with the hardware processor 420.

In certain example embodiments, the local controller 434 does not include a hardware processor 420. In such a case, the local controller 434 can include, as an example, one or more field programmable gate arrays (FPGA), one or more insulated-gate bipolar transistors (IGBTs), and/or one or more integrated circuits (ICs). Using FPGAs, IGBTs, ICs, and/or other similar devices known in the art allows the local controller 434 (or portions thereof) to be programmable and function according to certain logic rules and thresholds without the use of a hardware processor. Alternatively, FPGAs, IGBTs, ICs, and/or similar devices can be used in conjunction with one or more hardware processors 420.

The transceiver 425 of the local controller 434 can send and/or receive control and/or communication signals. Specifically, the transceiver 425 can be used to transfer data between the local controller 434 and the user 490, the network manager 480, the variable resistive loads 440, the GFCI breakers 410, the master controller 437, and/or the electrical load 475. The transceiver 425 can use wired and/or wireless technology. The transceiver 425 can be configured in such a way that the control and/or communication signals sent and/or received by the transceiver 425 can be received and/or sent by another transceiver that is part of the user 490, the network manager 480, the variable resistive loads 440, the GFCI breakers 410, the master controller 437, and/or the electrical load 475. The transceiver 425 can use any of a number of signal types, including but not limited to radio signals.

When the transceiver 425 uses wireless technology, any type of wireless technology can be used by the transceiver 425 in sending and receiving signals. Such wireless technology can include, but is not limited to, Wi-Fi, visible light communication, cellular networking, and Bluetooth. The transceiver 425 can use one or more of any number of suitable communication protocols (e.g., ISA100, HART) when sending and/or receiving signals. Such communication protocols can be stored in the protocols 472 of the storage repository 470. Further, any transceiver information for the user 490, the network manager 480, the variable resistive loads 440, the GFCI breakers 410, the master controller 437, and/or the electrical load 475 can be part of the stored data 474 (or similar areas) of the storage repository 470.

Optionally, in one or more example embodiments, the security module 428 secures interactions between the local controller 434, the user 490, the network manager 480, the variable resistive loads 440, the GFCI breakers 410, the master controller 437, and/or the electrical load 475. More specifically, the security module 428 authenticates communication from software based on security keys verifying the identity of the source of the communication. For example, user software may be associated with a security key enabling the software of the user 490 to interact with the local controller 434. Further, the security module 428 can restrict receipt of information, requests for information, and/or access to information in some example embodiments.

As mentioned above, the optional master controller 437 can be included in the system 499. In such a case, the master controller 437 can include one or more components and/or perform one or more functions described above with respect to a local controller 434. In other words, the master controller 437 can perform one or more functions that complement the functions performed by the one or more local controllers 434.

As stated above, the enclosure 400 (and so also the testing circuit assembly 430) can be placed in any of a number of environments. In such a case, the enclosure 400 can be configured to comply with applicable standards for any of a number of environments. For example, the enclosure 400 can be rated as a Division 1 or a Division 2 enclosure under NEC standards. Similarly, any of the components (e.g., the testing circuit assembly 430, the GFCI breakers 410) disposed within the enclosure 400 can allow the enclosure 400 to comply with applicable standards for any of a number of environments.

FIG. 5 illustrates one embodiment of a computing device 518 that implements one or more of the various techniques described herein, and which is representative, in whole or in part, of the elements described herein pursuant to certain example embodiments. Computing device 518 is one example of a computing device and is not intended to suggest any limitation as to scope of use or functionality of the computing device and/or its possible architectures. Neither should computing device 518 be interpreted as having any dependency or requirement relating to any one or combination of components illustrated in the example computing device 518.

Computing device 518 includes one or more processors or processing units 514, one or more memory/storage components 515, one or more input/output (I/O) devices 516, and a bus 517 that allows the various components and devices to communicate with one another. Bus 517 represents one or more of any of several types of bus structures, including a memory bus or memory controller, a peripheral bus, an accelerated graphics port, and a processor or local bus using any of a variety of bus architectures. Bus 517 includes wired and/or wireless buses.

Memory/storage component 515 represents one or more computer storage media. Memory/storage component 515 includes volatile media (such as random access memory (RAM)) and/or nonvolatile media (such as read only memory (ROM), flash memory, optical disks, magnetic disks, and so forth). Memory/storage component 515 includes fixed media (e.g., RAM, ROM, a fixed hard drive, etc.) as well as removable media (e.g., a Flash memory drive, a removable hard drive, an optical disk, and so forth).

One or more I/O devices 516 allow a customer, utility, or other user to enter commands and information to computing device 518, and also allow information to be presented to the customer, utility, or other user and/or other components or devices. Examples of input devices include, but are not limited to, a keyboard, a cursor control device (e.g., a mouse), a microphone, a touchscreen, and a scanner. Examples of output devices include, but are not limited to, a display device (e.g., a monitor or projector), speakers, outputs to a lighting network (e.g., DMX card), a printer, and a network card.

Various techniques are described herein in the general context of software or program modules. Generally, software includes routines, programs, objects, components, data structures, and so forth that perform particular tasks or implement particular abstract data types. An implementation of these modules and techniques are stored on or transmitted across some form of computer readable media. Computer readable media is any available non-transitory medium or non-transitory media that is accessible by a computing device. By way of example, and not limitation, computer readable media includes “computer storage media”.

“Computer storage media” and “computer readable medium” include volatile and non-volatile, removable and non-removable media implemented in any method or technology for storage of information such as computer readable instructions, data structures, program modules, or other data. Computer storage media include, but are not limited to, computer recordable media such as RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which is used to store the desired information and which is accessible by a computer.

The computer device 518 is connected to a network (not shown) (e.g., a local area network (LAN), a wide area network (WAN) such as the Internet, cloud, or any other similar type of network) via a network interface connection (not shown) according to some example embodiments. Those skilled in the art will appreciate that many different types of computer systems exist (e.g., desktop computer, a laptop computer, a personal media device, a mobile device, such as a cell phone or personal digital assistant, or any other computing system capable of executing computer readable instructions), and the aforementioned input and output means take other forms, now known or later developed, in other example embodiments. Generally speaking, the computer system 518 includes at least the minimal processing, input, and/or output means necessary to practice one or more embodiments.

Further, those skilled in the art will appreciate that one or more elements of the aforementioned computer device 518 is located at a remote location and connected to the other elements over a network in certain example embodiments. Further, one or more embodiments is implemented on a distributed system having one or more nodes, where each portion of the implementation (e.g., main controller 237) is located on a different node within the distributed system. In one or more embodiments, the node corresponds to a computer system. Alternatively, the node corresponds to a processor with associated physical memory in some example embodiments. The node alternatively corresponds to a processor with shared memory and/or resources in some example embodiments.

Example embodiments can provide for measuring and monitoring the performance parameters (specifically, the tripping points) of GFCI breakers. In some cases, one or more GFCI breakers are located within an enclosure. In such a case, the enclosures in which example embodiments are used are located in hazardous (e.g., explosion-proof) environments. As such, example embodiments can be used in environments where one or more applicable industry standards must be met by the enclosure. By tracking the various performance parameters of the GFCI breakers over time, example embodiments can indicate important information such as the useful life of a particular GFCI breaker to a user.

Example embodiments can include a testing circuit that includes one or more variable resistive loads. The testing circuit can adjust a variable resistive load to apply a range of simulated fault currents to the Earth ground of a GFCI breaker. By doing so, a number of GFCIs with varying tip points and/or a single GFCI with multiple tripping points can be tested and evaluated by the testing circuit. Specifically, the trip point of a GFCI breaker can be determined using example embodiments, rather than merely verifying that the GFCI breaker trips.

In some cases the testing circuit includes a controller to evaluate the results of testing a GFCI breaker. In addition, the controller can interactively communicate with a user (e.g., through the user interface, an alarm, an indicating light), a network manager, a maintenance department, an inventory management system, and/or any other entity that can be involved in the dissemination of information regarding the GFCI breaker. Example embodiments have a number of benefits over the present art, including but not limited to automated maintenance, increased reliability, enhanced user experience, and decreased risk of causing an enclosure to fall out of compliance with applicable industry standards.

Although embodiments described herein are made with reference to example embodiments, it should be appreciated by those skilled in the art that various modifications are well within the scope and spirit of this disclosure. Those skilled in the art will appreciate that the example embodiments described herein are not limited to any specifically discussed application and that the embodiments described herein are illustrative and not restrictive. From the description of the example embodiments, equivalents of the elements shown therein will suggest themselves to those skilled in the art, and ways of constructing other embodiments using the present disclosure will suggest themselves to practitioners of the art. Therefore, the scope of the example embodiments is not limited herein.

What is claimed is:

1. A testing circuit assembly, comprising:
a first variable resistive load configurable for a range of electrical resistances, wherein the first variable resistive load is configured to couple to at least one first ground fault circuit interrupter (GFCI) breaker and a current source; and
a first local controller coupled to the first variable resistive load, wherein the first local controller controls the first variable resistive load to simulate a range of fault currents, corresponding to the range of electrical resistances, flowing to the at least one first GFCI breaker to determine at least one actual trip point of the at least one first GFCI breaker,
wherein each electrical resistance in the range of electrical resistances corresponds to a fault current in the range of fault currents.

2. The testing circuit assembly of claim 1, wherein the first variable resistive load comprises a triac.

3. The testing circuit assembly of claim 1, wherein the electrical resistance in the range of electrical resistances changes continually.

4. The testing circuit assembly of claim 1, wherein the electrical resistance in the range of electrical resistances changes in discrete increments.

5. The testing circuit assembly of claim 1, wherein the first variable resistive load further comprises a variable impedance.

6. The testing circuit assembly of claim 1, further comprising:
a second variable resistive load configurable for the second range of electrical resistances, wherein the second variable resistive load is configured to couple to at least one second ground fault circuit interrupter (GFCI) breaker and the current source; and
a second local controller coupled to the second variable resistive load, wherein the second local controller controls the second variable resistive load to simulate the range of fault currents, corresponding to the range of electrical resistances, flowing to the at least one second GFCI breaker to determine at least one actual trip point of the at least one second GFCI breaker.

7. The testing circuit assembly of claim 1, further comprising:
a second variable resistive load configurable for the second range of electrical resistances, wherein the second variable resistive load is configured to couple to at least one second ground fault circuit interrupter (GFCI) breaker and the current source,
wherein the first local controller is further coupled to the second variable resistive load, wherein the first local controller controls the second variable resistive load to simulate the range of fault currents, corresponding to the range of electrical resistances, flowing to the at least one second GFCI breaker to determine at least one actual trip point of the at least one second GFCI breaker.

8. The testing circuit assembly of claim 1, wherein the first local controller evaluates a status of the at least one first GFCI breaker based on the at least one actual trip point of the at least one first GFCI breaker.

9. The testing circuit assembly of claim 8, wherein the first local controller communicates the status of the at least one GFCI breaker to a user.

10. The testing circuit assembly of claim 1, wherein the first local controller and the first variable resistive load are disposed, at least in part, on a circuit board.

11. The testing circuit assembly of claim 1, wherein the first local controller tracks the at least one actual trip point of the at least one GFCI breaker over time.

12. The testing circuit assembly of claim 1, further comprising:
a master controller coupled to the first local controller, wherein the master controller controls at least some functionality of the first local controller.

13. A ground fault circuit interrupter (GFCI) breaker testing system, the system comprising:
at least one GFCI breaker having at least one trip point; and
a testing circuit coupled to the at least one GFCI breaker, wherein the testing circuit simulates a range of fault currents through the at least one GFCI breaker, wherein the at least one trip point corresponds to at least one fault current within the range of fault currents.

14. The system of claim 13, wherein the at least one GFCI breaker is connected to Earth ground, and wherein the testing circuit provides a variable resistive load to the at least one GFCI breaker at the Earth ground.

15. The system of claim 13, wherein the testing circuit comprises:
a variable resistive load configurable for a range of electrical resistances, wherein the variable resistive load couples to at least one GFCI breaker and a current source; and
a local controller coupled to the variable resistive load, wherein the local controller controls the variable resistive load to simulate the range of fault currents, corresponding to the range of electrical resistances, flowing to the at least one GFCI breaker to determine at least one actual trip point of the at least one GFCI breaker,
wherein each resistive load in the range of resistive loads corresponds to a fault current in the range of fault currents.

16. The system of claim 15, further comprising:
a power supply coupled to the testing circuit, wherein the power supply generates power that is converted to the range of fault currents at the first variable resistive load.

17. A controller for a testing circuit, the controller comprising:
a control engine that follows a plurality of instructions to:
control a variable resistive load through which a current flows to a ground fault circuit interrupter (GFCI) breaker as a range of fault currents; and
determine whether the fault current in the range of fault currents at which the GFCI breaker trips.

18. The controller of claim 17, further comprising:
a memory that stores the plurality of instructions; and
a hardware processor that executes the plurality of instructions for the control engine.

19. The controller of claim 17, wherein the fault current in the range of fault currents is measured by an energy metering module coupled to the control engine.

20. The controller of claim 17, wherein the control engine tracks the fault current of the GFCI breaker over time.
